(19) United States
(12) Patent Application Publication
(10) Pub. No.: US 2024/0354477 A1
(43) Pub. Date: Oct. 24, 2024

(54) CONSTANT, EQUAL, OR OPPOSITE REGISTERS OR PORTS DETECTION DURING LOGIC SYNTHESIS

(71) Applicant: Synopsys, Inc., Sunnyvale, CA (US)

(72) Inventors: Navneet KAKKAR, Bengaluru (IN); Sridhar KELADI, Bengalore (IN)

(21) Appl. No.: 18/137,382

(22) Filed: Apr. 20, 2023

(51) Int. Cl. G06F 30/327; G06F 30/33

(52) U.S. Cl. CPC G06F 30/327; G06F 30/33

(57) ABSTRACT

Certain aspects are directed to apparatus and methods for logic synthesis. One example method generally includes: receiving a logic design including a representation of a plurality of registers and ports; detecting one or more constant, equal, or opposite registers or ports of the plurality of registers and ports by analyzing logic across a hierarchy boundary identified for the logic synthesis; and generating a netlist by modifying the logic based on the detection.

### TECHNICAL FIELD

The present disclosure generally relates to performing logic synthesis, and more particularly, performing logic synthesis by detecting constant, opposite, or equal registers or ports.

### BACKGROUND

Logic synthesis is an important step in designing and manufacturing integrated circuits (ICs). Logic synthesis involves the transformation of a high-level hardware description language (HDL) into a low-level gate-level netlist. Logic synthesis plays an important role in electronic design automation (EDA) flows by providing a way to quickly and efficiently implement a design for a target device. Logic synthesis aims to optimize a netlist in terms of area, power, and performance while satisfying certain design constraints. One of the key challenges in logic synthesis is dealing with the ever-increasing complexity of IC designs. As the number of gates and the design size grows, the synthesis operation must be able to handle the resulting increase in computational complexity.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are directed to a method for logic synthesis. The method generally includes: receiving a logic design including a representation of a plurality of registers and ports; detecting one or more constant, equal, or opposite registers or ports of the plurality of registers and ports by analyzing logic across a hierarchy boundary identified for the logic synthesis; and generating a netlist by modifying the logic based on the detection.

Certain aspects of the present disclosure are directed to an apparatus for logic synthesis. The apparatus generally includes: a memory, and one or more processors coupled to the memory, the one or more processors being configured to: receive a logic design including a representation of a plurality of registers and ports; detect one or more constant, equal, or opposite registers or ports of the plurality of registers and ports by analyzing logic across a hierarchy boundary identified for the logic synthesis; and generate a netlist by modifying the logic based on the detection.

Certain aspects of the present disclosure are directed to a non-transitory computer-readable medium having instructions stored thereon, that when executed by one or more processors, cause the one or more processors to: receive a logic design including a representation of a plurality of registers and ports; detect one or more constant, equal, or opposite registers or ports of the plurality of registers and ports by analyzing logic across a hierarchy boundary identified for logic synthesis; and generate a netlist by modifying the logic based on the detection.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates an example circuit including a constant register, in accordance with certain aspects of the present disclosure.

FIG. 2 is an example circuit including equal registers, in accordance with certain aspects of the present disclosure.

FIG. 3 is an example circuit including opposite registers, in accordance with certain aspects of the present disclosure.

FIG. 4 illustrates an example circuit including a multiplexer, in accordance with certain aspects of the present disclosure.

FIG. 5 illustrates a circuit having exclusive OR (XOR) gates, coupled to respective registers, that may be detected as constant registers, in accordance with certain aspects of the present disclosure.

FIG. 6 is a flow diagram illustrating example operations for logic synthesis, in accordance with certain aspects of the present disclosure.

FIG. 7 illustrates an example set of processes used during the design, verification, and fabrication of an article of manufacture.

FIG. 8 illustrates an example computer system having a compiler, in accordance with certain aspects of the present disclosure.

### DETAILED DESCRIPTION

Logic synthesis converts register-transfer logic (RTL) to a gate-level netlist to improve power, performance, and area (PPA). Designs contain many objects which could be constants, equals, or opposites to one another, as described in more detail herein. These objects include registers, hierarchy ports, and combinational gates. Detecting constants, equals, or opposite objects is an important part of logic synthesis to improve PPA. Some aspects of the present disclosure are directed towards a compiler which may be a tool for converting RTL to a graphic data stream. The compiler may perform logic synthesis and optimization (e.g., early as part of the logic synthesis flow), which involves optimizations or modifications on combinational and sequential logic to improve the PPA. Dependencies and interactions between different objects of a circuit design may be analyzed, and opportunities to combine objects into a more efficient form may be identified. For example, the compiler may detect constant, equal, or opposite objects and in response, either remove or combine the objects.

Constant propagation involves detecting and propagating constants through registers, ports, and gates. The compiler algorithm for detecting constants may rely on combinational optimizations to detect and wire up constants to registers, ports, and gates. The constant propagation algorithm propagates detected constants forward at strategic points in the logic design flow. Register merging involves detecting equal/opposite registers and removing the redundant registers.

Certain aspects of the present disclosure provide a constant, equal and opposite register and port detection operation in the compiler. The operation provides a runtime-efficient, cross-module, verifiable, satisfiability (SAT)-based self-sufficient method to detect and optimize constant/equal/opposite netlist objects. Thus, the operations provided herein reduce processors utilization associated with performing logic synthesis. The aspects described herein also facilitate logic synthesis that provides a more efficient logic design, reducing power consumption and reducing hardware area consumption. As used herein, “optimize” generally refers to reducing logic (e.g., removing redundant logic) during logic synthesis.

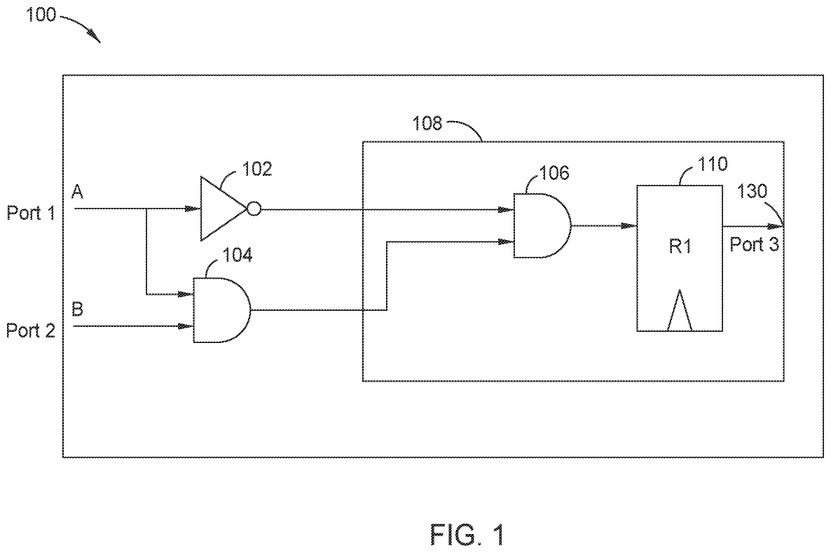

FIG. 1 illustrates an example circuit 100 including a constant register, in accordance with certain aspects of the present disclosure. As shown, circuit 100 may include a register 110 having an input coupled to an output of an AND gate 106. The inputs of the AND gate 106 are coupled to the respective outputs of an inverter 102 and an AND gate 104. As shown, the input of inverter 102 is driven by an input signal A. The inputs of the AND gate 104 are driven by input signals A and B. Thus, regardless of the logic levels of input signals A and B, the input to register 110 will be logic low. For example, if input signal A is logic low, then the output of AND gate 104 will be logic low and the output of AND gate 106 will be logic low. If input signal A is logic high, then the output of inverter 102 is logic low, and the output of the AND gate 106 is logic low. Thus, register 110 may be referred to as a constant register.

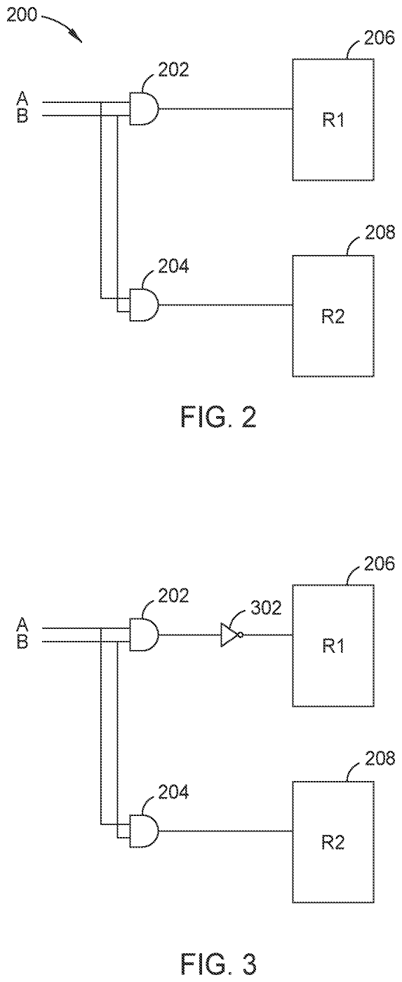

FIG. 2 is an example circuit 200 including equal registers, in accordance with certain aspects of the present disclosure. As shown, both registers 206, 208 have inputs driven by outputs of respective AND gates 202, 204. Moreover, the AND gates 202, 204 are both driven by input signals A and B. Therefore, regardless of the logic level of input signals A and B, the inputs to registers 206, 208 will be the same. Therefore, registers 206, 208 may be detected as equal registers. If detected, the compiler may combine the registers 206, 208 into a single register.

FIG. 3 is an example circuit 300 including opposite registers, in accordance with certain aspects of the present disclosure. As shown, the output of AND gate 202 may be coupled to the input of register 206 through an inverter 302. Therefore, the inputs of registers 206, 208 will be complementary (e.g., when the input of register 206 is logic high, the input of register 208 is logic low, and vice versa).

Certain compiler implementations may miss certain constant, equal, or opposite objects if the associated logic crosses a hierarchy boundary. A hierarchy boundary refers to a logical division between different levels of abstraction in a circuit design. The hierarchy boundary may be user defined and allows designers to manage the complexity of large digital circuits by breaking them down into smaller, more manageable blocks.

Referring back to FIG. 1, combinational optimization processes may not be performed across the hierarchy boundary 108, and hence, the register 110 may not be found as a constant register. In other words, a compiler may detect constant registers by analyzing logic (e.g., interactions between inverter 102 and AND gates 104, 106) within a certain module boundary (e.g., a user-defined module boundary). Suppose the compiler only analyses the logic within boundary 108. In that case, the compiler may not detect that register 110 is a constant register because the compiler may only consider the AND gate 106 (e.g., without considering the inverter 102 and AND gate 104).

In certain aspects of the present disclosure, the compiler may detect constant, equal, opposite registers and hierarchical ports at an earlier stage of logic synthesis as compared to conventional implementations. A hierarchical port refers to an input or output of a portion of a circuit design (e.g., a module). For example, in FIG. 1, node 130 may be an output of a module (e.g., having module boundary 108) and may be considered as a port to be considered for constant, equal, or opposite detection. Moreover, constant, equal, or opposite registers and hierarchical ports may be detected across hierarchy boundaries. For instance, instead of the detection being limited to logic within boundary 108, the boundary for the detection may be expanded past boundary 108 to include logic within a portion of or the entire input path for register 110 (e.g., to include inverter 102 and AND gate 104).

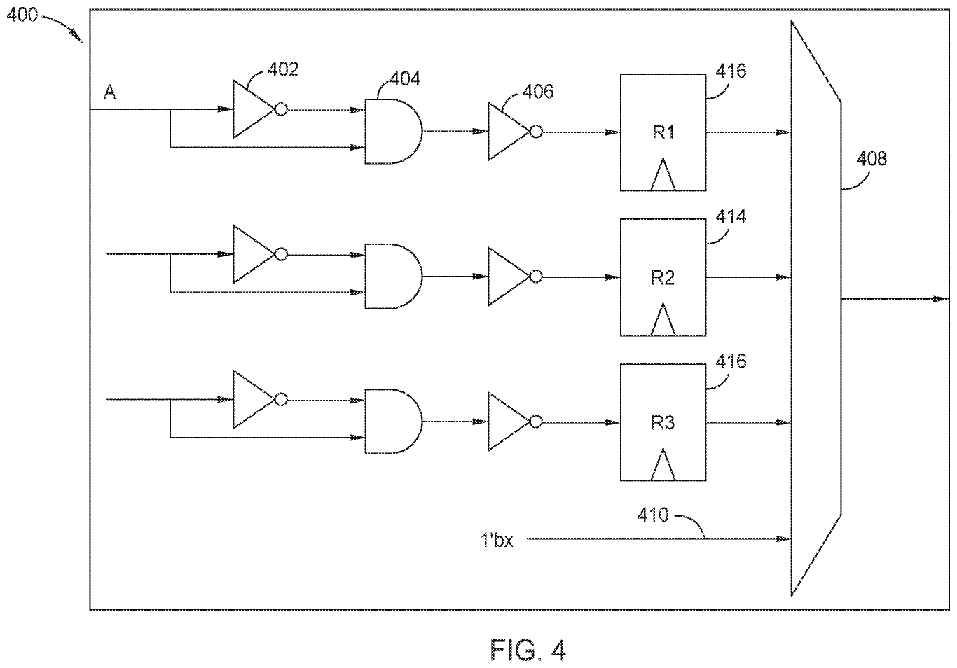

FIG. 4 illustrates an example circuit 400 including a multiplexer 408, in accordance with certain aspects of the present disclosure. Typically, a logic synthesis flow includes discrete flow steps. For example, a first constant propagation process may be performed, followed by a multiplexer optimization process, followed by a log simplification process, and followed by a second constant propagation step. Constant propagation involves identifying and replacing expressions and variables with their constant values. For example, constant registers as described with respect to FIG. 1 may be replaced with a constant value. Multiplexer optimization is the process of designing and implementing a multiplexer (e.g., multiplexer 408) with the fewest number of logic gates and inputs. For instance, if all the inputs to a multiplexer is the same, the multiplexer may be removed. Logic simplification is a process used to reduce the complexity of a logical expression or function. Logic simplification aims to create a functionally equivalent expression that uses fewer logic gates.

As shown in FIG. 4, the inputs of multiplexer 408 may be coupled to outputs of registers 412, 414, 416 and an input node 410 receiving a “don't care” input (labeled “1′bx”). The inputs of each of registers 412, 414, 416 may be coupled to logic, including inverters and an AND gate. For instance, the input of register 416 may be coupled to an output of inverter 406. The input of inverter 406 may be coupled to an output of AND gate 404. An input signal A may be provided directly to an input of the AND gate 404 and may be provided to another input of the AND gate 404 through an inverter 402. Thus, the output of AND gate 404 will be logic low (e.g., since one of the inputs to the AND gate 404 will always be logic low); thus, the output of inverter 406 will be logic high. The same logic configuration is implemented for the input paths of registers 412, 414. Thus, the registers 412, 414, 416 may be constant and equal registers, which should allow for optimization to be performed for multiplexer 408.

However, due to the phase ordering problem, multiplexer optimization may not occur. For instance, while a first constant propagation may be performed during the logic synthesis flow, constant propagation may not be performed for the constant registers 412, 414, 416 because logic simplification has not yet been performed to identify the constants provided to the inputs of the registers 412, 414, 416. As a result, the subsequent step of multiplexer optimization assumes non-constant registers at the multiplexer inputs, and thus, may assume that the don't care input is as logic low (e.g., as a default logic level). Later, logic simplification may occur, identifying that the inputs of the registers 412, 414, 416 are constant at logic high. Then, another constant propagation step may be performed, removing the constant registers 412, 414, 416 (e.g., replacing them with constant logic high input). However, multiplexer optimization has already occurred in the logic synthesis flow, and thus, the identification and propagation of constants is too late to facilitate multiplexer optimization. This phase ordering problem leads to suboptimal PPA.

In certain aspects of the present disclosure, constant, equal, or opposite detection and propagation may be performed earlier in the logic synthesis flow. For example, constant, equal, or opposite detection and propagation may be performed before multiplexer optimization. In some aspects, SAT techniques may be used to analyze complex logic for constants, equal, or opposite objects. SAT is a problem-solving approach that aims to determine whether a given logical formula is satisfiable or not. For instance, the SAT technique may be used to determine whether there exists a set of values to variables that would make a formula true. If such a set of values exists, then the formula is said to be satisfiable. Such self-sufficient, early detection removes the dependency on combinational optimization engines and eliminates (or at least reduces) the phase ordering problem described herein, which benefits all logic optimizations.

SAT is runtime intensive. Thus, applying SAT on all netlist objects may be impractical. In some aspects, only registers and hierarchy ports (e.g., inputs and outputs of module boundaries) may be chosen as SAT candidates for analysis, keeping the runtime manageable.

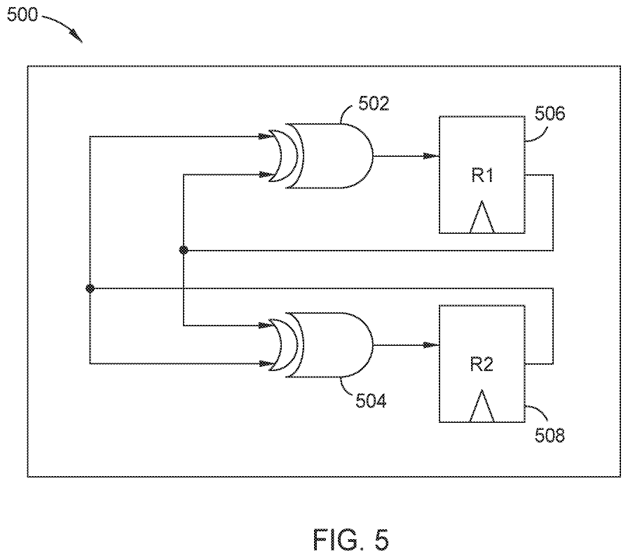

FIG. 5 illustrates a circuit 500 having XOR gates 502, 504 coupled to respective registers 506, 508 that may be detected as constant registers, in accordance with certain aspects of the present disclosure. For example, the inputs of registers 506, 508 may be coupled to outputs of respective XOR gates 502, 504, as shown. An input of each of XOR gates 502, 504 may be coupled to an output of register 506 and another input of each of XOR gates 502, 504 may be coupled to an output of register 508. In some cases, constant, equal, or opposite registers (e.g., such as registers 506, 508) that involve complex detection analysis may not be detected. For example, if each of the registers 506, 508 of circuit 500 are analyzed separately, the compiler may not detect that registers 506, 508 are constant registers (e.g., have constant inputs). The interactions between registers 506, 508 would have to be analyzed to determine that registers 506, 508 are constant registers. If detected as constants, both registers 506, 508 may be removed and replaced with a node providing a constant logic low signal (e.g., assuming initial states of logic low). In some aspects of the present disclosure, an assume-and-disprove technique may be used to detect constant, equal, opposite registers or ports. The assume-and-disprove technique involves assuming a hypothesis to be true, then attempting to find a logical contradiction that proves the hypothesis to be false. For instance, the compiler may assume a hypothesis that registers 506, 508 are constant registers and perform operations to disprove the hypothesis. Using assume-and-disprove techniques facilitates the detection of constant, equal, or opposite objects that would involve handling of complex interactions across registers.

In some cases, the full detection algorithm may be repeated multiple times to take advantage of combinational optimizations, resulting in high runtimes for the compiler. Some aspects of the present disclosure are directed toward reducing the runtime of a compiler. For example, although constant, equal, or opposite objects may be detected early, some restrictions may prevent committing the detected constant, equal, opposites for optimization immediately after detection. For example, a user may set a restriction with regard to modifications of logic during specific portions of logic synthesis.

In some aspects, the compiler may first identify the subset of objects (e.g., registers and ports) which are allowable for immediate commitment for optimization and to a netlist. For example, the compiler may first identify objects (e.g., a subset S1) that are constant, equal, or opposite objects. Then, restrictions may be applied and the detection algorithm may be repeated to identify the objects (e.g., within S1) that are allowable to commit (e.g., a subset S2 that are allowable to commit) for optimization. The repetition of the detection algorithm may be performed quickly as it only considers the subset S1 when detecting the subset S2 that is allowable to commit for optimization. The subset S2 (constant/equal/opposites) may be propagated and committed to the netlist. The candidates (e.g., a subset S3, which is S1 less S2) which are not allowed to be committed for propagation during this re-evaluation may be marked (e.g., stored) for re-evaluation later during the flow. For example, later down the flow, some restrictions may be relaxed and candidates may be re-evaluated. At this stage, only the subset S3 (e.g., earlier rejected and marked candidates) may be re-evaluated, resulting in reduced runtime during re-evaluations.

Logic synthesis flow may include a verification process that verifies whether optimized logic is acceptable (e.g., still meets a specified function). In some cases, the framework for logic synthesis may not create a methodical guidance to the verification tool for constant, equal, or opposite registers or ports. In some aspects, as described herein, registers and ports may be treated as first-class objects for detection (e.g., are detected early during the flow). Thus, verification guidance may be reliably issued. In other words, the detected constant, equal, or opposite objects may be indicated for verification reliably due to the early detection.

In some aspects of the present disclosure, registers and hierarchy ports may be treated as boundaries. For example, constant, equal, or opposite registers and ports may be identified early, allowing the combinational optimization and propagation algorithms to work within the hierarchy port and register boundaries without sacrificing any PPA. For example, referring back to FIG. 4, register 416 may function as a boundary for multiplexer optimization. With registers and ports functioning as boundaries, combinational optimizations can happen in parallel within these boundaries.

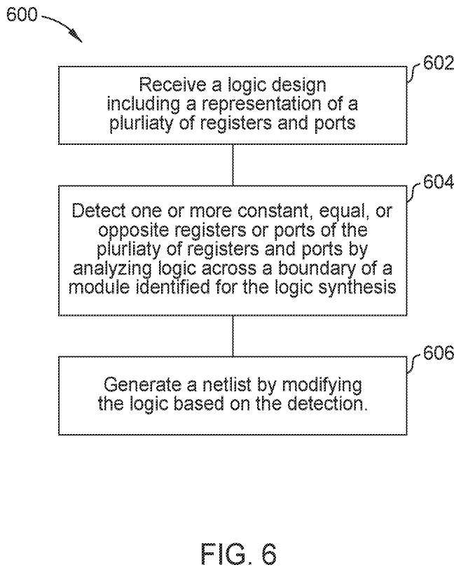

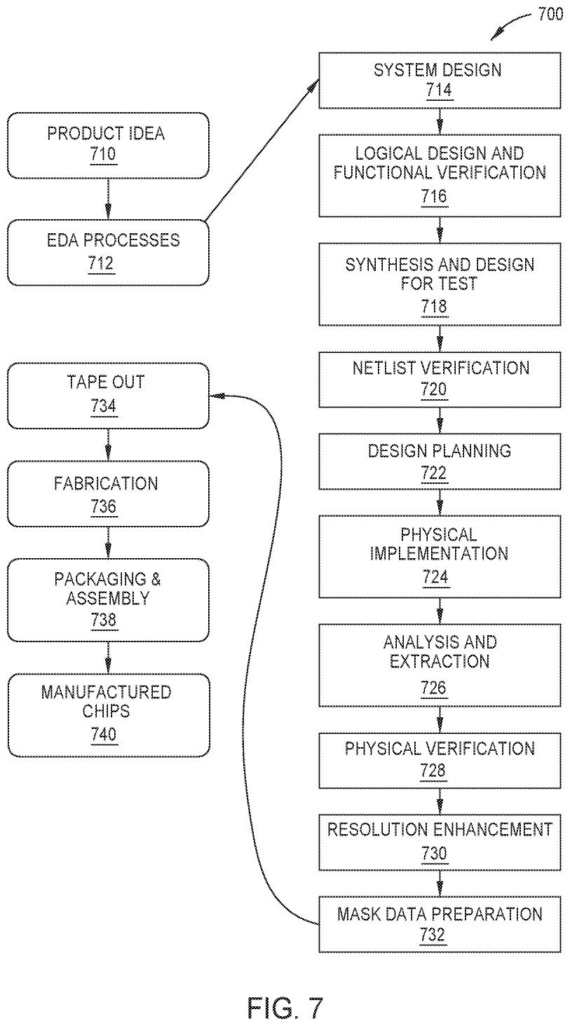

FIG. 6 is a flow diagram illustrating example operations 600 for logic synthesis, in accordance with certain aspects of the present disclosure. The operations 600 may be performed, for example, by a compiler (e.g., compiler 827 of the processing device 802).

The operations 600 begin, at block 602, with the compiler receiving a logic design including a representation of a plurality of registers and ports. At block 604, the compiler may detect one or more constant, equal, or opposite registers or ports of the plurality of registers and ports by analyzing logic across a boundary of a module identified for the logic synthesis. In some aspects of the present disclosure, the detection may be performed using Boolean satisfiability (SAT) analysis. In some aspects, the detection may be performed using assume-and-disprove analysis.

For example, detecting the one or more constant registers or ports may include detecting whether a logic cone (e.g., logic level) at an input of one or more registers or one or more ports is constant. Detecting the equal registers or ports may include detecting whether logic cones (e.g., logic levels) at inputs of registers or ports are equal. Detecting opposite registers or ports may include detecting whether logic cones (e.g., logic levels) at inputs of registers or ports are opposites.

In some aspects, the detection of the constant, equal, or opposite registers or ports may be performed prior to performing a logic reduction (e.g., logic optimization) for any other objects of the logic design during the logic synthesis. For example, the other objects may include any logic gate such as a multiplexer.

In some aspects, the compiler may perform a verification process to identify whether the modification of the logic is acceptable based on the detection of the one or more constant, equal, or opposite registers or ports. In some aspects, the compiler may also perform logic reductions in parallel based on boundaries associated with registers or ports.

At block 606, the compiler may generate a netlist by modifying the logic (e.g., performing logic optimization) based on the detection. In some aspects, the compiler may identify a subset of the constant, equal, and opposite registers or ports that are constrained from modification at a first step during the logic synthesis. The compiler may store the subset of the constant, equal, and opposite registers or ports, and re-evaluate the stored subset of the constant, equal, and opposite registers or ports to generate the netlist at a second step during the logic synthesis after the first step.

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level representation may be used to design circuits and systems, using a hardware description language (‘HDL’) such as VHDL, Verilog, System Verilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 7. The processes described by be enabled by EDA products (or tools).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

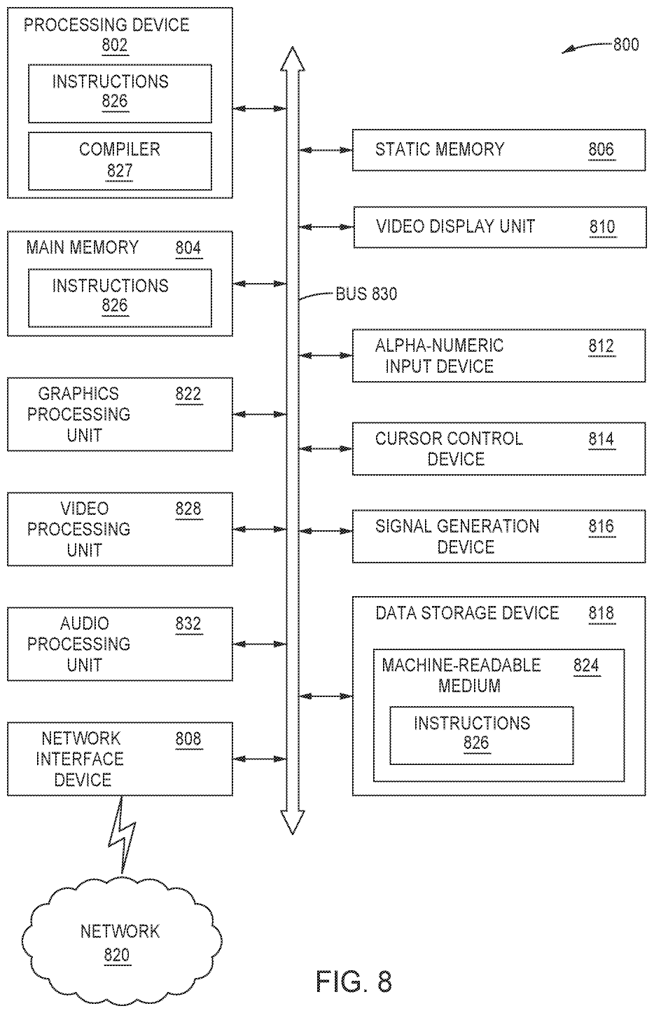

A storage subsystem of a computer system (such as computer system 800 of FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

In some aspects of the present disclosure, the processing device 802 may include a compiler 827. The compiler 827 may perform logic synthesis processes as described herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method for logic synthesis, comprising:
receiving a logic design including a representation of a plurality of registers and ports;
detecting, by a processing device, one or more registers or ports of the plurality of registers and ports having a constant logic cone, opposite logic cones, or equal logic cones by analyzing logic across a hierarchy boundary identified for the logic synthesis; and
generating a netlist by modifying the logic based on the detection.

2. The method of claim 1, wherein the detection of the one or more registers or ports is performed prior to performing logic reduction for any other objects of the logic design during the logic synthesis.

3. The method of claim 2, wherein the other objects include a multiplexer.

4. The method of claim 1, wherein the detection is performed using Boolean satisfiability (SAT) analysis.

5. The method of claim 1, wherein the detection is performed using assume-and-disprove analysis.

6. The method of claim 1, further comprising:
identifying a subset of the registers or ports that are constrained from modification at a first step during the logic synthesis;
storing the subset of the registers or ports; and
re-evaluating the stored subset of the registers or ports to generate the netlist at a second step during the logic synthesis after the first step.

7. The method of claim 1, further comprising performing a verification process to identify whether the modification of the logic is acceptable based on the detection of the one or more registers or ports.

8. The method of claim 1, further comprising performing logic reductions in parallel based on boundaries associated with registers or ports.

9. The method of claim 1, wherein detecting the one or more registers or ports having the constant logic cone includes detecting whether a logic cone at an input of one or more registers or one or more ports is constant.

10. The method of claim 1, wherein detecting the registers or ports having the equal logic cones includes detecting whether logic cones at inputs of registers or ports are equal.

11. The method of claim 1, wherein detecting the registers or ports having the opposite logic cones includes detecting whether logic cones at inputs of registers or ports are opposites.

12. The method of claim 1, wherein detecting the one or more registers or ports includes detecting constant, equal, or opposite registers or ports for a plurality of circuit design portions in parallel.

13. An apparatus comprising:
a memory; and
one or more processors coupled to the memory, the one or more processors being configured to:
receive a logic design including a representation of a plurality of registers and ports;
detect one or more constant, equal, or opposite registers or ports of the plurality of registers and ports by analyzing logic across a hierarchy boundary identified for logic synthesis; and
generate a netlist by modifying the logic based on the detection.

14. The apparatus of claim 13, wherein the one or more processors are configured to detect the constant, equal, or opposite registers or ports prior to performing logic reduction for any other objects of the logic design during the logic synthesis.

15. The apparatus of claim 14, wherein the other objects include a multiplexer.

16. The apparatus of claim 13, wherein the one or more processors are configured to detect the one or more constant, equal, or opposite registers or ports using Boolean satisfiability (SAT) analysis.

17. The apparatus of claim 13, wherein the one or more processors are configured to detect the one or more constant, equal, or opposite registers or ports using assume-and-disprove analysis.

18. The apparatus of claim 13, wherein the one or more processors are configured to:
identify a subset of the constant, equal, and opposite registers or ports that are constrained from modification at a first step during the logic synthesis;
store, in the memory, the subset of the constant, equal, and opposite registers or ports; and
re-evaluate the stored subset of the constant, equal, and opposite registers or ports to generate the netlist at a second step during the logic synthesis after the first step.

19. The apparatus of claim 13, wherein the one or more processors are further configured to perform a verification process to identify whether the modification of the logic is acceptable based on the detection of the one or more constant, equal, or opposite registers or ports.

20. A non-transitory computer-readable medium having instructions stored thereon, that when executed by one or more processors, cause the one or more processors to:
receive a logic design including a representation of a plurality of registers and ports;
detect one or more constant, equal, or opposite registers or ports of the plurality of registers and ports by analyzing logic across a hierarchy boundary identified for logic synthesis; and
generate a netlist by modifying the logic based on the detection.
